(19) United States
(12) Patent Application Publication
(10) Pub. No.: US 2025/0240884 A1
(43) Pub. Date: Jul. 24, 2025

(54) METAL-CERAMIC SUBSTRATE WITH CONTACT AREA

(71) Applicant: Heraeus Electronics GmbH & Co. KG, Hanau (DE)

(72) Inventors: Richard WACKER, Hanau (DE); Fabian SIPOS, Chisoda (RO); Ciprian BATISTA, Chisoda (RO); Andrei-Stefan LEAH, Chisoda (RO)

(21) Appl. No.: 19/032,318

(22) Filed: Jan. 20, 2025

(30) Foreign Application Priority Data
Jan. 24, 2024 (EP) 24153588.9

(51) Int. Cl. H05K 1/03; H05K 3/10

(52) U.S. Cl. CPC H05K 1/0306; H05K 3/10

(57) ABSTRACT

A metal-ceramic substrate, to an electronic component comprising a metal-ceramic substrate, and to a method for producing a metal-ceramic substrate. The metal-ceramic substrate comprises: a) a ceramic body comprising a primary boundary surface, b) a metal layer comprising a primary boundary surface, wherein the metal layer is connected over its surface to the ceramic body, and wherein the metal layer comprises a structuring region which comprises (i) partially solid material and (ii) partially non-solid material, and c) a contact area, comprising silver, arranged on the metal layer, wherein in a cross-section through the metal-ceramic substrate perpendicular to the primary boundary surface of the ceramic body, the structuring region has a geometry as described in the patent.

### CROSS-REFERENCE TO RELATED APPLICATION

This application claims priority pursuant to 35 U.S.C. 119 (a) to European Patent Office Application No. 24153588.9, filed Jan. 24, 2024, which application is incorporated herein by reference in its entirety.

### BACKGROUND

The present invention relates to a metal-ceramic substrate, to an electronic component comprising a metal-ceramic substrate, and to a method for producing a metal-ceramic substrate.

Metal-ceramic substrates play an important role in the field of power electronics. They are a crucial element when building electronic components and ensure rapid dissipation of large quantities of heat during operation of said components. Metal-ceramic substrates typically consist of a ceramic layer and a metal layer which is bonded to the ceramic layer.

### BRIEF SUMMARY

Several methods are known from the prior art for bonding the metal layer to the ceramic layer. In the so-called DCB (“direct copper bonding”) method, a copper foil is provided superficially with a copper compound (usually copper oxide), which has a lower melting point than copper, by reacting copper with a reactive gas (usually oxygen). When the copper foil treated in this way is applied to a ceramic body and the composite is heated, the copper compound melts and wets the surface of the ceramic body, so that a stable cohesive bond is achieved between the copper foil and the ceramic body. This method is described, for example, in U.S. Pat. No. 3,744,120 A or DE 2319854 C2.

In an alternative method, metal foils can be bonded to ceramic bodies at temperatures of approximately 650 to 1000° C., wherein a special solder is used which contains a metal having a melting point of at least 700° C. (usually silver) and an active metal. The role of the active metal is to react with the ceramic material and to thus facilitate a bonding of the ceramic material to the remaining solder, forming a reaction layer, while the metal having a melting point of at least 700° C. serves to bond said reaction layer to the metal foil. For example, JP4812985 B2 proposes bonding a copper foil to a ceramic body using a solder containing 50 to 89 weight percent silver, as well as copper, bismuth and an active metal. With this method, it is possible to reliably join the copper foil to the ceramic body. Alternatively, silver-free solders can be used to connect metal foils to ceramic bodies. These solders are based, for example, on high-melting metals (in particular copper), low-melting metals (such as bismuth, indium or tin), and active metals (such as titanium). Such a technique is proposed, for example, in DE 102017114893 A1. This technique basically results in a new, independent class of compounds, since the basis of the solders used is formed by another metal (copper instead of silver), which leads to changed material properties and results in an adaptation with regard to the other solder components and modified joining conditions.

In the construction of electronic components, metal-ceramic substrates are usually equipped with a chip. To equip the metal-ceramic substrate with a chip, it is usually necessary that the area of the metal-ceramic substrate to be equipped with the chip is provided with a silver-containing contact area. By providing the silver-containing contact area, the chip can be more easily connected to the metal-ceramic substrate using common processes such as sintering or soldering. To create the contact area, the metal-ceramic substrate is usually first treated in certain regions with an etching solution in order to form the desired structuring. The contact area is then provided by partially applying a silver-containing coating to the surface of the structured metal-ceramic substrate.

The metal-ceramic substrates produced in this way are usually exposed to high temperature changes during operation as part of electronic components. While during breaks in operation-depending on the environment—the temperatures can be, for example, −20° C. or lower, the temperature of the metal-ceramic substrates can easily rise to over 150° C. during operation. The metal-ceramic substrates are regularly exposed to these temperature differences. Due to the different thermal expansion coefficients of the metal and the ceramic, repeated temperature changes can lead to the metal layer detaching from the ceramic body (peeling), which results in a loss of performance. Therefore, high thermal shock resistance is a key criterion for the suitability of metal-ceramic substrates for applications in electronics, especially in power electronics.

It would therefore be desirable to further increase the thermal shock resistance of metal-ceramic substrates.

An object of the present invention is therefore to provide a metal-ceramic substrate which has an increased resistance to thermal shock.

This object is achieved by the metal-ceramic substrate of claim 1. The invention therefore provides a metal-ceramic substrate comprising
a) a ceramic body comprising a primary boundary surface,
b) a metal layer comprising a primary boundary surface, wherein the metal layer is connected over its surface to the ceramic body, and wherein the metal layer comprises a structuring region comprising
   (i) partially solid material and
   (ii) partially non-solid material, and
c) a contact area, comprising silver, arranged on the metal layer, wherein:

in a cross-section through the metal-ceramic substrate perpendicular to the primary boundary surface of the ceramic body, the structuring region has a geometry, wherein the following requirement is met:

$$S ( {BC}_{solid} ) / S ( {BC}_{total} ) > 60 \% ,$$

wherein:
S(BCₜₒₜₐₗ) stands for the total length of the line between points B and C, and
S(BC_{solid}) stands for the length of the line between points B and C that intersects solid material,
where points B and C are determined as follows:
   1. the line of best fit between the ceramic body and the metal layer is determined;
   2. the contour line which separates the solid material from the non-solid material is determined;
   3. point A, at which a perpendicular to the line of best fit intersects the contour line, is determined on the perpendicular to the line of best fit, at a distance of 150 μm from the line of best fit;
   4. point B, at which a perpendicular to the line of best fit intersects the contour line, is determined on the perpendicular to the line of best fit, at a distance of 80 μm from the line of best fit; and
   5. point C, at which a straight line intersects the line of best fit, is determined on the straight line passing through points A and B; and
wherein the contour line extends from the primary boundary surface of the metal layer to the primary boundary surface of the ceramic body, wherein the contour line has an upper half and a lower half, wherein the upper half of the contour line extends from the primary boundary surface of the metal layer toward the primary boundary surface of the ceramic body and the lower half of the contour line extends from the primary boundary surface of the ceramic body toward the primary boundary surface of the metal layer, and wherein the solid material in the region adjacent to the upper half of the contour line has a higher silver content than in the region adjacent to the lower half of the contour line.

Furthermore, the invention relates to an electronic component comprising such a metal-ceramic substrate.

In addition, the invention relates to a method for producing a metal-ceramic substrate.

The metal-ceramic substrate according to the invention comprises a ceramic body comprising a primary boundary surface.

The ceramic body is preferably a body formed from ceramic. The body can have any geometry but is preferably designed as a cuboid. The ceramic body comprises boundary surfaces—in the case of a cuboid, six boundary surfaces. The primary boundary surface in this document preferably refers to the boundary surface (very particularly preferably the boundary surface with the greatest surface area) which is connected to the metal layer over its surface. The primary boundary surface is particularly preferably the boundary surface (very particularly preferably the boundary surface with the greatest surface area) which is connected over its surface to the metal layer which comprises a structuring region, and very particularly preferably the boundary surface (in particular the boundary surface with the greatest surface area) which is connected over its surface to the metal layer on which a contact area comprising silver is arranged. The primary boundary surface preferably lies in the primary extension plane of the ceramic body or runs parallel to it. Accordingly, the primary extension plane of the ceramic body is preferably understood to be a plane that runs parallel to the primary boundary surface of the ceramic body or encloses it.

The ceramic of the ceramic body is preferably an insulating ceramic. According to a preferred embodiment, the ceramic is selected from the group consisting of oxide ceramics, nitride ceramics, and carbide ceramics. According to a further preferred embodiment, the ceramic is selected from the group consisting of metal oxide ceramics, silicon oxide ceramics, metal nitride ceramics, silicon nitride ceramics, boron nitride ceramics, and boron carbide ceramics. According to a particularly preferred embodiment, the ceramic is selected from the group consisting of aluminum nitride ceramics, silver nitride ceramics, and aluminum oxide ceramics (such as ZTA (“zirconia toughened alumina”) ceramics). According to a further very particularly preferred embodiment, the ceramic body consists of (1) at least one element selected from the group consisting of silicon and aluminum, (2) at least one element selected from the group consisting of oxygen and nitrogen, optionally (3) at least one element selected from the group consisting of (3a) rare earth metals, (3b) metals of the second main group of the periodic table of elements, (3c) zirconium, (3d) copper, (3e) molybdenum and (3f) silicon, and optionally (4) unavoidable impurities. According to yet another very particularly preferred embodiment, the ceramic body is free of bismuth, gallium, and zinc.

The ceramic body preferably has a thickness in the range of 0.05-10 mm, more preferably a thickness in the range of 0.1-5 mm, and particularly preferably a thickness in the range of 0.15-3 mm.

The metal-ceramic substrate according to the invention comprises a metal layer which comprises a primary boundary surface, wherein the metal layer is connected to the ceramic body over its surface, and wherein the metal layer comprises a structuring region which comprises (i) partially solid material and (ii) partially non-solid material.

The metal layer comprises boundary surfaces. The metal layer comprises a primary boundary surface. The primary boundary surface is preferably referred to herein as the boundary surface (very particularly preferably the boundary surface with the greatest surface area) which faces away from the ceramic body. Consequently, the primary boundary surface is preferably referred to as the boundary surface (very particularly preferably the boundary surface with the greatest surface area) on which the contact area comprising silver is arranged. The primary boundary surface preferably lies in the primary extension plane of the metal layer or runs parallel to it. Accordingly, the primary extension plane of the metal layer is preferably understood to be a plane that runs parallel to the primary boundary surface of the metal layer or encloses it. The primary boundary surface of the metal layer preferably runs parallel to the primary boundary surface of the ceramic body and is particularly preferably spaced apart from it.

The metal layer is preferably integrally bonded to the ceramic body. According to a preferred embodiment, the metal layer is bonded to the ceramic body via a DCB (Direct Copper Bonding) process. According to a further preferred embodiment, the metal layer is connected to the ceramic body via a brazing process. The brazing process can, for example, be an AMB (Active Metal Brazing) process, wherein preferably silver-free brazing alloys (the silver content is then, for example, less than 1.0 percent by weight, based on the solid content of the brazing alloy) or silver-containing brazing alloys (the silver content is then, for example, at least 50 percent by weight, based on the solid content of the brazing alloy) are used. Consequently, the metal layer may also comprise a bonding layer in contact with the ceramic body. The bonding layer can be, for example, a solder layer (in particular a brazing layer) or a diffusion layer.

The metal layer is connected over its surface to the ceramic body. Accordingly, the metal layer is preferably connected over its surface to the primary boundary surface of the ceramic body. The metal layer is preferably not connected to the entire primary boundary surface of the ceramic body. In particular, it can be provided that the primary boundary surface of the ceramic body is larger than the surface of the metal layer connected to the ceramic body. In these cases, the primary boundary surface of the ceramic body protrudes. In addition, the metal layer is preferably structured. Structuring is preferably understood to mean recesses in the metal layer, which separate individual portions of the metal layer from one another and thus electrically insulate them. Such structuring is usually created using etching techniques.

Accordingly, the metal layer comprises a structuring region. The structuring region is a portion of the metal layer that contains a structuring. A structuring is preferably a recess in the metal layer. Consequently, the primary boundary surface of the metal layer comprises metal of the metal layer, which is interrupted by the recess in the structuring region.

The structuring region comprises a region comprising solid material and a region comprising non-solid material.

The region comprising solid material preferably contains (i) metal of the metal layer (optionally including a bonding layer (if present)) and (ii) metal of the contact area (in particular silver).

The region comprising non-solid material preferably contains gas-phase material. Therefore, the non-solid material preferably comprises gas-phase material. The non-solid material is preferably gas-phase material with which the recess in the metal layer is filled. This gas-phase material usually comes from the ambient atmosphere. Preferably, the gas-phase material therefore contains at least one element selected from the group consisting of nitrogen, oxygen and noble gases. Most preferably, the gas-phase material is a gas mixture, in particular air.

According to a preferred embodiment, the recess extends in a direction perpendicular to the primary boundary surface of the ceramic body from the primary boundary surface of the ceramic body to the primary boundary surface of the metal layer. The recess preferably forms a channel which is filled to at least 50 percent by volume, more preferably to at least 80 percent by volume, even more preferably to at least 90 percent by volume, particularly preferably to at least 95 percent by volume and very particularly preferably to at least 99 percent by volume, completely, with non-solid material.

The metal layer preferably comprises at least one metal selected from the group consisting of copper, aluminum and molybdenum. According to a further preferred embodiment, the metal layer comprises at least one metal which is selected from the group consisting of copper and molybdenum. According to a very particularly preferred embodiment, the metal layer comprises copper. According to a further preferred embodiment, the metal layer consists of copper and unavoidable impurities. According to a further preferred embodiment, the proportion of copper is at least 60 percent by weight, preferably at least 65 percent by weight, even more preferably at least 70 percent by weight and particularly preferably at least 75 percent by weight, based on the total weight of the metal layer (preferably including any bonding layer that may be present).

According to a preferred embodiment, the metal layer is produced by bonding a copper foil (preferably a foil made of high-purity copper) to a ceramic body. According to a preferred embodiment, the connection can be made via a DCB (Direct Copper Bonding) process or via a brazing process. The brazing process can, for example, be an AMB (Active Metal Brazing) process, wherein preferably silver-free brazing alloys (the silver content is then, for example, less than 1.0 percent by weight, based on the solid content of the brazing alloy) or silver-containing brazing alloys (the silver content is then, for example, at least 50 percent by weight, based on the solid content of the brazing alloy) are used. In this case, the metal layer may comprise, in addition to the copper originating from the copper foil, also metals of a bonding layer, in particular metals of a solder layer (for example a brazing layer) or a diffusion layer.

The metal layer preferably has a thickness in the range of 0.01-10 mm, particularly preferably a thickness in the range of 0.03-5 mm, and very particularly preferably a thickness in the range of 0.05-3 mm.

The metal-ceramic substrate according to the invention comprises a contact area, comprising silver, arranged on the metal layer. The contact area preferably serves to facilitate the connection of a chip to the metal layer. Chips are preferably connected to the metal layer by sintering, soldering or gluing. Since in particular the attachment of chips to the metal of the metal layer of a metal-ceramic substrate is not easy, the metal layer is preferably provided with a contact area. The contact area is preferably made of silver or a silver-containing alloy. In the case of a silver-containing alloy, it contains at least 50 percent silver by weight, based on the weight of the silver alloy. Preferably, a contact area is provided on the metal layer of the metal-ceramic substrate at all positions where the metal-ceramic substrate is later to be equipped with chips. The contact area can be formed on the metal layer of the metal-ceramic substrate using different techniques. For example, it is possible to provide the contact area by depositing a silver-containing layer. The deposition of the silver-containing layer is preferably carried out chemically (e.g., electrochemically) or physically. The chemical deposition of the silver-containing layer can be carried out, for example, galvanically or electrolessly. Preferably, the chemical deposition of the silver-containing layer is carried out electrolessly by applying a silver-containing solution, with a charge exchange between the metals, wherein metal of the metal layer partially dissolves while the silver in the solution is deposited. According to a preferred embodiment, the silver-containing solution contains a silver salt and particularly preferably silver nitrate. According to a particularly preferred embodiment, the silver-containing solution is an acidic solution of silver nitrate, and particularly preferably a nitric acid solution of silver nitrate. The physical deposition of the silver-containing layer can be carried out, for example, by gas phase deposition. Preferred methods for gas phase deposition are in particular electron beam deposition, laser beam deposition, arc discharge deposition or cathode sputtering.

The structuring region of the metal layer of the metal-ceramic substrate has the geometry described herein. The geometry of the structuring region is determined in a cross-section through the metal-ceramic substrate perpendicular to the primary boundary surface of the ceramic body.

In a cross-section through the metal-ceramic substrate perpendicular to the primary boundary surface of the ceramic body, the structuring region of the metal layer has a geometry, wherein the following requirement is met:

$$S ( {BC}_{solid} ) / S ( {BC}_{total} ) > 60 \% ,$$

S(BCₜₒₜₐₗ) stands for the total length of the line between points B and C, and
S(BC_{solid}) stands for the length of the line between points B and C that intersects solid material.

According to a preferred embodiment, the structuring region of the metal layer in a cross-section through the metal-ceramic substrate perpendicular to the primary boundary surface of the ceramic body has a geometry, wherein the ratio S(BC_{solid})/S(BCₜₒₜₐₗ) is >70%, more preferably >80%, even more preferably >85%, particularly preferably >90% and very particularly preferably >95%.

According to a further preferred embodiment, the structuring region of the metal layer in a cross-section through the metal-ceramic substrate perpendicular to the primary boundary surface of the ceramic body has a geometry, wherein the ratio S(BC_{solid})/S(BCₜₒₜₐₗ) is in the range of 70-100%, particularly preferably in the range of 80-100% and very particularly preferably in the range of 80-99%.

To determine points B and C, a cross-section of the structuring region of the metal layer of the metal-ceramic substrate is observed. The cross-section runs perpendicular to the primary boundary surface of the ceramic body. Preferably, the observation of the cross-section can be carried out by cutting the metal-ceramic substrate perpendicular to the primary boundary surface of the ceramic body and capturing an image of the cross-section thus obtained through a light microscope.

### BRIEF DESCRIPTION OF THE SEVERAL VIEWS OF THE DRAWINGS

The points B and C of the line BC can be determined in the cross-section as described below. For illustration purposes, reference is made to FIGS. 1 and 2 as examples.

FIG. 1 shows a schematic representation of a metal-ceramic substrate of this type;

FIG. 2 shows schematically a metal-ceramic substrate according to the invention with a structuring region, wherein the solid material in the region adjacent to the upper half of the contour line has a higher silver content than in the region adjacent to the lower half of the contour line;

FIG. 3 shows a part of a cross-section through a metal-ceramic substrate according to the invention;

FIG. 4 shows an example of a light micrograph of the cross-section of a section of a structuring region of the copper layer of a copper-ceramic substrate according to Example 1; and

FIG. 5 shows an example of a light micrograph of the cross-section of a section of a structuring region of the copper layer of a copper-ceramic substrate according to Comparative Example 1.

### DETAILED DESCRIPTION

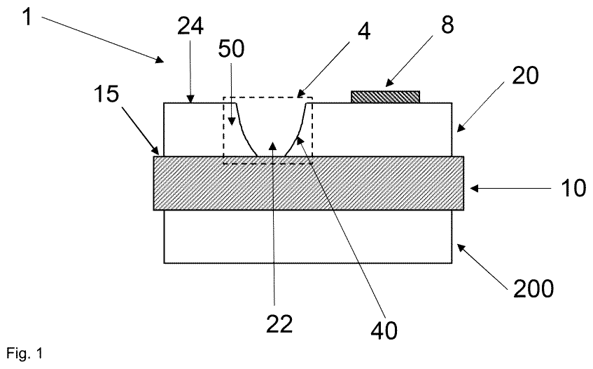

The metal-ceramic substrate 1 shown in FIG. 1 comprises a ceramic body 10. The ceramic body 10 comprises a primary boundary surface 15. The metal-ceramic substrate 1 comprises a metal layer 20. The metal layer 20 comprises, on the upper side facing away from the primary boundary surface 15 of the ceramic body 10, a primary boundary surface 24 parallel to the primary boundary surface 15 of the ceramic body 10. The metal layer 20 is connected over its surface to the primary boundary surface 15 of the ceramic body 10. In the embodiment according to FIG. 1, the metal-ceramic substrate 1 further comprises a further metal layer 200 which is connected to the ceramic body 10 over its surface. On the metal layer 20 there is a contact area 8 comprising silver. The metal layer 20 comprises a structuring. This is formed by a recess 22 in the metal layer 20. The recess 22 contains non-solid material. The structuring region 4 partially comprises the metal of the metal layer 20 and the recess 22. Therefore, the structuring region 4 partially comprises solid material 50, which is formed by the metal of the metal layer 20, and non-solid material (for example gas-phase material) with which the recess 22 is filled. The gas-phase material is usually ambient air. The solid material 50 is separated from the non-solid material of the recess 22 by a contour line 40. The primary boundary surface 24 of the metal layer 20 comprises metal of the metal layer 20, which is interrupted by the recess 22 in the structuring region. The recess 22 extends in a direction perpendicular to the primary boundary surface 15 of the ceramic body 10 from the primary boundary surface 24 of the metal layer 20 to the primary boundary surface 15 of the ceramic body 10, and preferably forms a channel which is completely or predominantly filled with non-solid material.

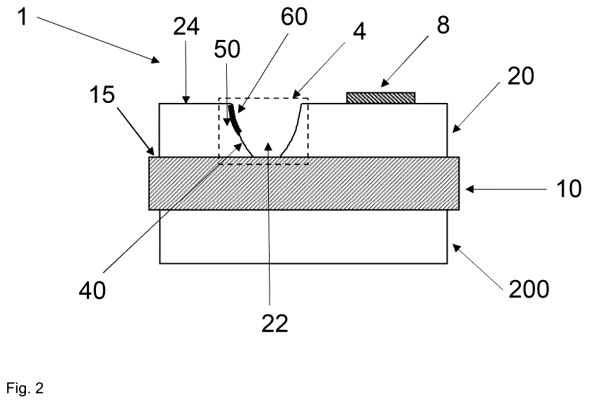

The metal-ceramic substrate shown in FIG. 2 has the same basic structure as the metal-ceramic substrate shown in FIG. 1. The contour line 40 has an upper half and a lower half. The upper half of the contour line 40 extends from the primary boundary surface 24 of the metal layer 20 toward the primary boundary surface 15 of the ceramic body 10. The lower half of the contour line 40 extends from the primary boundary surface 15 of the ceramic body 10 toward the primary boundary surface 24 of the metal layer 20. The solid material 50 comprises silver 60 in the region adjacent to the upper half of the contour line 40. In the region adjacent to the lower half of the contour line 40, the solid material contains no, or less, silver 60.

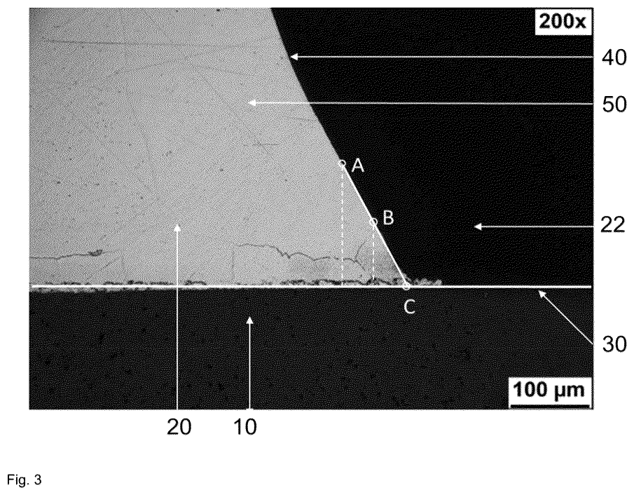

In the part of a cross-section through a metal-ceramic substrate according to the invention shown in FIG. 3, a portion of a structuring region can be seen. A region of the ceramic body 10 which is connected over its surface to a region of a metal layer 20 is shown. The contour line 40 separates the solid material 50 from the non-solid material of the recess 22 in the metal layer 20.

The determination of points B and C of the line BC in the cross-section is preferably carried out in several steps:

In a first step, the line of best fit 30 between the ceramic body 10 and the metal layer 20 is determined. For this purpose, the area of the ceramic body 10 and the area of the metal layer 20 are determined optically, and the line of best fit 30 is defined as the boundary between the ceramic body 10 and the metal layer 20 that can be observed in the cross-section.

In a second step, the contour line 40 is determined which separates the solid material 50 from the non-solid material of the recess 22. The solid material 50 is determined optically; this is usually the material of the metal layer 20. The non-solid material is also determined optically. The non-solid material is usually a gas-phase material with which the structuring is filled—as a recess 22 in the metal layer 20.

In a third step, point A, at which a perpendicular to the line of best fit 30 intersects the contour line 40, is determined on the perpendicular to the line of best fit 30, at a distance of 150 μm from the line of best fit 30.

In a fourth step, point B, at which a perpendicular to the line of best fit 30 intersects the contour line 40, is determined on the perpendicular to the line of best fit 30, at a distance of 80 μm from the line of best fit 30.

In a fifth step, point C, at which a straight line intersects the line of best fit 30, is determined on the straight line passing through points A and B.

The section of the metal-ceramic substrate perpendicular to the primary boundary surface of the ceramic body and the capturing of the image of the cross-section thus obtained, through a light microscope, (incident light/bright field) are preferably carried out as described below:

In a first step, a cuboid sample blank comprising a rectangular base in the range of 100 mm² up to 400 mm² is first cut out of the metal-ceramic substrate to be examined, by sawing using a diamond saw blade at a low rotational speed and using a lubricant (Exakt), perpendicular to a plane formed by the by the primary boundary surface of the ceramic body of the metal-ceramic substrate. The sample blank accordingly comprises a sample surface which is supplied to the investigation. This sample surface therefore runs perpendicular to the plane formed by the by the primary boundary surface of the ceramic body of the metal-ceramic substrate before sawing. It therefore comprises portions on the ceramic body and the metal layer (including the optionally present bonding layer). The sample blank is first embedded in a casting mold with a low-shrinkage epoxy resin (Caldo-Fix, Struers), wherein the sample surface is oriented perpendicular to the mold wall. The epoxy resin is then cured at 75° C. in a drying oven. After curing, the sample surface of the sample blank is mechanically polished with an automated polishing device (Tegrapole, Struers) in order to achieve a roughness of 1 μm or less.

In a second step, a structuring region comprising partially solid material and partially non-solid material is identified in the metal layer using a light microscope (Leica, DM6000M, incident light/bright field) at a magnification of 200× in the analysis zone. Solid material and non-solid material can be clearly distinguished in the structuring region due to the different colors.

The lengths of the lines S(BCₜₒₜₐₗ) and S(BC_{solid}) are preferably determined in a standard manner, for example using image analysis software (e.g., IMS Client, Imagic).

Preferably, the term “in a cross-section” as used herein refers to a (preferably representative) total of cross-sections, particularly preferably to at least ten cross-sections, very particularly preferably to not more than 20 cross-sections, and in particular to ten cross-sections. The cross-sections preferably run parallel to one another and are evenly spaced from one another.

To determine the ratio S(BC_{solid})/S(BCₜₒₜₐₗ) for a metal-ceramic substrate being observed, the following procedure is preferably used:
1. At least ten, particularly preferably ten, different cross-sections of the structuring region are examined;
2. the ratio S(BC_{solid})/S(BCₜₒₜₐₗ) is determined for each of these cross-sections; and,
3. the ratios S(BC_{solid})/S(BCₜₒₜₐₗ) are averaged for each of these cross-sections to obtain the ratio S(BC_{solid})/S(BCₜₒₜₐₗ) for the metal-ceramic substrate under observation.

According to a preferred embodiment, the sample standard deviation SSD of the ratio S(BC_{solid})/S(BCₜₒₜₐₗ) over at least ten different cross-sections of the structuring region of the metal layer, more preferably over no more than 20 different cross-sections of the structuring region of the metal layer, and very particularly preferably over ten different cross-sections of the structuring region of the metal layer, is not more than 10%, more preferably not more than 7%, particularly preferably not more than 5%, and very particularly preferably not more than 3%. The sample standard deviation SSD is determined using the following formula:

$$SSD = \sqrt{\frac{1}{n - 1} {\sum }_{i = 1}^{n} {( {X}_{i} - \overline{X} )}^{2}} ,$$

wherein:
n=number of individual values for the ratio S(BC_{solid})/S(BCₜₒₜₐₗ),
Xᵢ=single value for the ratio S(BC_{solid})/S(BCₜₒₜₐₗ) and
X̅=average of the individual values for the ratio S(BC_{solid})/S(BCₜₒₜₐₗ).

According to the invention, in a cross-section through the metal-ceramic substrate perpendicular to the primary boundary surface of the ceramic body, the structuring region has a geometry, wherein the contour line extends from the primary boundary surface of the metal layer to the primary boundary surface of the ceramic body, wherein the contour line has an upper half and a lower half, wherein the upper half of the contour line extends from the primary boundary surface of the metal layer toward the primary boundary surface of the ceramic body and the lower half of the contour line extends from the primary boundary surface of the ceramic body toward the primary boundary surface of the metal layer, and wherein the solid material in the region adjacent to the upper half of the contour line has a higher silver content than in the region adjacent to the lower half of the contour line.

According to the invention, the contour line therefore extends from the primary boundary surface of the metal layer to the primary boundary surface of the ceramic body. The contour line preferably does not extend along the primary boundary surface of the ceramic and not along the primary boundary surface of the metal layer. Therefore, the contour line preferably extends over an area that does not include the primary boundary surface of the ceramic and the primary boundary surface of the metal layer.

The contour line has an upper half and a lower half. The upper half of the contour line extends from the primary boundary surface of the metal layer toward the primary boundary surface of the ceramic body. The lower half of the contour line extends from the primary boundary surface of the ceramic toward the primary boundary surface of the metal layer.

According to the invention, the solid material in the region adjacent to the upper half of the contour line has a higher silver content than in the region adjacent to the lower half of the contour line. According to a preferred embodiment, the ratio of the silver content in the solid material in the region adjacent to the lower half of the contour line to the silver content in the solid material in the region adjacent to the upper half of the contour line is less than 0.8, more preferably less than 0.5, even more preferably less than 0.3, particularly preferably less than 0.1 and very particularly preferably less than 0.05.

The region of the solid material adjacent to the contour line preferably has a width in the range of 0.3-1.0 μm, particularly preferably a width in the range of 0.5-0.6 μm and very particularly preferably a width of 0.5 μm. The contour line thus preferably describes the outline of the solid material, wherein the composition of the solid material (including the silver content) is determined using the method described above, preferably in a region which is limited by (i) the primary boundary surface of the metal layer, (ii) the primary boundary surface of the ceramic body, (iii) the contour line and (iv) a parallel shift of the contour line in the direction of the solid material by 0.3-1.0 μm, particularly preferably by 0.5-0.6 μm and very particularly preferably by 0.5 μm. The contour line is preferably divided into an upper half and a lower half halfway between the primary boundary surface of the metal layer and the primary boundary surface of the ceramic body, wherein the upper half of the contour line extends from the primary boundary surface of the metal layer toward the primary boundary surface of the ceramic body and the lower half of the contour line extends from the primary boundary surface of the ceramic body toward the primary boundary surface of the metal layer. The area of solid material to be measured therefore consists of an upper half, which is adjacent to the upper half of the contour line, and a lower half, which is adjacent to the lower half of the contour line.

The silver content of the solid material in the region adjacent to the upper half of the contour line and the silver content of the solid material in the region adjacent to the lower half of the contour line are preferably determined by energy dispersive X-ray spectroscopy (EDX) coupled with scanning electron microscopy (SEM) (SEM-EDX).

In SEM-EDX, a focused primary electron beam is guided (scanned) over the sample surface point by point. The scattered electrons are detected using a detector, wherein the number of electrons per pixel results in a microscopic image of the sample surface in grayscale. In addition, the primary electron beam excites the sample to emit characteristic X-ray radiation, wherein the elements in the sample and their weight proportion can be determined by analyzing the energy spectrum using an EDX detector.

For the examination, for example, a scanning electron microscope (JSM-6060 SEM, JEOL Ltd) with a silicon drift EDX detector (NORAN, Thermo Scientific Inc) and analytical software (Pathfinder Mountaineer EDS System, for example Version 2.8, Thermo Scientific Inc) are used. For scanning electron microscopy, the following settings can be used: magnification: 200×, acceleration voltage=10 kV, working distance=10 mm, spot size (50-60) (set to reach 25%+/−5% of the dead time of the EDX detector). The EDX spectrum can be captured using the following settings of the EDX detector: live time=30 s, rate=auto, low energy cutoff=100 keV, high energy cutoff=auto (per SEM acceleration voltage). Depending on the selected magnification and the thickness of the metal layer, several SEM-EDX measurements may be required to image the entire structuring region.

The silver content is measured in the region adjacent to the upper half of the contour line and in the region adjacent to the lower half of the contour line, at a minimum of five and particularly preferably at ten representative positions within each area. The silver content is preferably understood to be the arithmetic mean of the respective individual measurements.

Surprisingly, it was found that metal-ceramic substrates with the geometry according to the invention have an increased thermal shock resistance compared to metal-ceramic substrates from the prior art. These metal-ceramic substrates have a high proportion of solid material in the metal layer at the boundary to the surface of the ceramic body. In contrast, it was found that the proportion of solid material in the metal layer at the boundary to the surface of the ceramic body is significantly lower in metal-ceramic substrates from the prior art if they comprise a contact area comprising silver arranged on the metal layer.

Without being bound to an explanation, this could be due to the fact that, in the prior art, the metal-ceramic substrate produced is usually first structured and then silver-plated on the surface to create the contact area; however, the already structured areas of the surface of the metal-ceramic substrate are only inadequately masked during the silver-plating. For this purpose, the areas of the surface of the structured metal-ceramic substrate that are not to be coated with silver are usually masked first before silver-plating. A film (e.g., a dry film) is usually used for masking. This film spans the structurings of the metal-ceramic substrate so that the structurings are covered with the film but not completely lined, especially not in an area close to the ceramic body. The subsequent silver-plating is usually carried out by dipping the structured and masked metal-ceramic substrate into a bath containing a solution containing silver ions. The solution containing silver ions can wash under the masking film so that it comes into direct contact with the underlying structuring. During the silver-plating process, metal ions are electrochemically dissolved from the metal layer of the metal-ceramic substrate in the region of the structuring and replaced by silver ions. It has been shown that the dissolution of metal ions from the metal layer and the deposition of silver ions take place in spatially separated areas near the ceramic body. Therefore, the deposition of silver often takes place directly on the surface of the structuring, while the metal ions are preferably released from an area close to the ceramic body (approx. up to 50 μm distance from the ceramic body surface), so that the surface of the structuring close to the ceramic body is gradually removed as the contact time with the silver-ion-containing solution progresses. This results in the removal of solid material—in particular the metal of the metal foil—from the metal foil in the area close to the ceramic body and thus creates a weak point for the detachment of the metal layer from the ceramic body, which has a detrimental effect on the thermal shock resistance. The removal of solid material in the structuring could therefore be due to a lack of lining of the structuring with the masking film. According to the invention, however, a structuring region is created which comprises sufficient amounts of solid material in the region close to the ceramic body, whereby detachment of the metal layer from the ceramic body can be prevented and an improvement in the thermal shock resistance can be achieved.

The solid material comprises silver in the region adjacent to the upper half of the contour line. The reason for this is that, according to one embodiment, the mask is applied by a printing process before silver-plating. Since the structuring of the metal-ceramic substrate usually has a curved geometry, the structuring is (almost) completely covered with the mask in an area close to the ceramic body, which improves the thermal shock resistance. In contrast, an area of the structuring further away from the ceramic body is usually not completely masked, so that it is at least partially coated with silver in the subsequent silver-plating step.

According to a preferred embodiment, the metal-ceramic substrate comprises a further (second) metal layer which is connected to the ceramic body over its surface. The further metal layer is preferably connected over its surface to the boundary surface facing away from the primary boundary surface of the ceramic (and preferably running parallel thereto). The further (second) metal layer can be of the same nature as the (first) metal layer or can differ in its properties from the (first) metal layer. For the properties of the further (second) metal layer, reference is made to the above explanations regarding the (first) metal layer.

The metal-ceramic substrate according to the invention can in particular be used for applications in electronics, especially for the field of power electronics.

The invention therefore also provides an electronic component which comprises the metal-ceramic substrate according to the invention.

According to a preferred embodiment, the electronic component comprises the metal-ceramic substrate according to the invention and at least one chip. The at least one chip is preferably connected over its surface to the contact area, comprising silver, arranged on the (first) metal layer. Therefore, the electronic component preferably comprises a chip which is in contact with the (first) metal layer of the metal-ceramic substrate via the contact area comprising silver.

According to a further preferred embodiment, the metal-ceramic substrate of the electronic component comprises a further (second) metal layer. The further (second) metal layer is preferably connected over its surface to the ceramic body. In this case, the further metal layer is preferably connected over its surface to the boundary surface of the ceramic body facing away from the primary boundary surface of the ceramic body (and preferably running parallel thereto).

According to a further preferred embodiment, the electronic component comprises a base plate. Said base plate is preferably connected over its surface to the further (second) metal layer of the metal-ceramic substrate. Alternatively, the further (second) metal layer of the metal-ceramic substrate can be designed as a heat sink.

According to a further preferred embodiment, the electronic component comprises a metal-ceramic substrate which comprises a (first) metal layer and a further (second) metal layer (wherein the further metal layer is preferably connected over its surface to the boundary surface facing away from the primary boundary surface of the ceramic body), a base plate and at least one chip, wherein the at least one chip is connected over its surface to the first metal layer of the metal-ceramic substrate via the contact area, comprising silver, arranged on the metal layer and the base plate is connected over its surface to the further (second) metal layer of the metal-ceramic substrate.

The metal-ceramic substrate according to the invention can be obtained by different manufacturing processes.

The invention also provides a method for producing a metal-ceramic substrate provided with a structuring and a contact area comprising silver.

The method for producing a metal-ceramic substrate provided with a structuring and a contact area comprising silver comprises the steps of:
a) providing a metal-ceramic substrate, comprising
   a1) a ceramic body and
   a2) a metal layer connected over its surface to the ceramic body,
b) structuring the metal layer,
c) applying a mask to the structured metal layer by applying a liquid medium comprising a masking agent to the structured metal layer in certain regions, and solidifying the masking agent,
d) depositing a silver-containing layer on the unmasked regions of the structured metal layer to obtain a contact area comprising silver, and
e) removing the mask.

In step a), a metal-ceramic substrate is first provided.

This metal-ceramic substrate comprises a ceramic body and a metal layer that is connected over its surface to the ceramic body. The metal-ceramic substrate can be a standard metal-ceramic substrate. The ceramic body and the metal layer may have a composition as described above with respect to the metal-ceramic substrate. The metal layer can preferably be integrally bonded to the ceramic body, as also described above with respect to the metal-ceramic substrate.

In step b) the metal layer is structured. Structuring is preferably understood to mean recesses in the metal layer, which separate individual portions of the metal layer from one another and thus electrically insulate them. The structurings therefore preferably expose areas of the ceramic body. Such structuring is usually created using etching techniques. For example, an etching mask can first be applied to the metal layer. The etching mask serves to protect the masked regions of the metal layer from etching in an etching step. This ensures that only those areas of the metal layer of the metal-ceramic substrate that are unmasked and intended for structuring are accessible for etching. Consequently, the etching mask is designed in such a way that no etching of the masked regions of the metal layer occurs during the etching step. The type of etching mask is not limited further. The etching mask can, for example, be a standard negative mask or positive mask. Standard etching resists can be used to produce the etching mask. These etching resists preferably contain a curable polymer (for example a light-curable polymer) and can be applied to the metal layer, for example, as a film (for example as a dry film) or as a liquid (for example by printing or spraying). After application, the etching resists can be treated in a suitable manner (e.g., cured by light irradiation) to obtain the etching mask. According to one possible embodiment, a photosensitive film is applied to the metal layer of the metal-ceramic substrate, and is then exposed to the areas to be masked in order to obtain the etching mask. The unexposed regions of the photosensitive film can then be removed in a conventional manner (for example using a sodium carbonate solution).

After applying the etching mask to the metal layer, unmasked regions of the metal layer are preferably etched to obtain a structuring. Etching is preferably carried out in a standard, conventional manner. Etching is therefore preferably carried out using a standard etching solution. According to a preferred embodiment, the etching solution is selected from the group consisting of FeCl₃ etching solutions and CuCl₂ etching solutions. If necessary, a further etching solution can be used, for example to structure unmasked regions of an optionally included bonding layer. According to a preferred embodiment, the further etching solution can be selected from the group consisting of etching solutions containing hydrogen peroxide and etching solutions containing ammonium peroxodisulfate. For example, the further etching solution may be an etching solution containing ammonium fluoride and fluoroboric acid (for example HBF₄) as well as hydrogen peroxide and/or ammonium peroxodisulfate.

Preferably, after unmasked regions of the metal layer are etched to obtain a structuring, the etching mask is removed. The etching mask can be removed in a standard manner. For this purpose, the metal-ceramic substrate can be treated, for example, with an alkaline solution (e.g., a 2.5% sodium hydroxide solution) to remove the etching mask.

In step c), a mask is applied to the structured metal layer by applying a liquid medium comprising a masking agent to the structured metal layer in certain regions and solidifying the masking agent.

The mask serves to protect the masked regions of the metal layer in step d) from deposition of a silver-containing layer. This ensures that a silver-containing layer is deposited only on the unmasked regions of the metal layer of the metal-ceramic substrate. Consequently, the mask is designed in such a way that no silver-containing layer can be deposited on the masked regions of the metal layer of the metal-ceramic substrate.

According to a preferred embodiment, the structured metal layer to which the mask is applied also comprises the structuring region, particularly preferably the structuring region between the primary boundary surface of the metal layer and the primary boundary surface of the ceramic. Thus, in particular, the areas of the metal layer in the vicinity of the ceramic body are also provided with a mask in order to protect them from dissolution during the deposition of a silver-containing layer, in particular upon contact with the solution containing silver ions, in step d).

To apply the mask, a liquid medium containing a masking agent is applied to the structured metal layer in certain regions and the masking agent is solidified.

The liquid medium is preferably a medium that is liquid at room temperature and normal pressure. The liquid medium is preferably a medium comprising a polar solvent, particularly preferably water. According to a preferred embodiment, the liquid medium is selected from the group consisting of solutions and suspensions.

The liquid medium comprises a masking agent. The masking agent is preferably designed so that it can be solidified. The masking agent is not further restricted. According to a preferred embodiment, the masking agent is curable, in particular UV-curable. The UV-curable masking agent preferably comprises at least one compound which is selected from the group consisting of monomers and oligomers. According to a particularly preferred embodiment, the UV-curable masking agent comprises at least one compound selected from the group consisting of acrylates, epoxies and unsaturated polyester resins. The liquid medium preferably further comprises a photoinitiator. The photoinitiator may, for example, be a compound that decomposes upon absorption of UV light and forms a reactive species capable of initiating the polymerization and curing of the UV-curable masking agent. In addition, the liquid medium may contain other components such as colorants and additives.

The liquid medium, which contains a masking agent, is applied to the structured metal layer in certain regions. For this purpose, the liquid medium is preferably applied to the areas of the structured metal layer that are to be masked and protected from the deposition of a silver-containing layer in step d).

The liquid medium is preferably applied to the structured metal layer by printing, spraying or painting. According to a particularly preferred embodiment, the liquid medium is applied by printing using an inkjet process.

After application of the liquid medium, the masking agent contained therein is preferably solidified. For this purpose, the masking agent is preferably cured. Curing can be achieved, for example, by irradiating the liquid medium with UV light so that the masking agents contained in the liquid medium (in particular monomers or oligomers) polymerize.

According to a preferred embodiment, the application of the mask to the structured metal layer comprises an additive masking step. The additive masking step means the application of a masking agent. According to a further preferred embodiment, the application of the mask to the structured metal layer does not comprise a subtractive masking step. A subtractive masking step is understood to mean the partial removal of masking agent applied and solidified, for example in an additive masking step, in particular before the deposition of a silver-containing layer on the unmasked regions of the structured metal layer to obtain a contact area comprising silver according to step d). According to this preferred embodiment, the liquid medium comprising the masking agent is applied only to the regions of the structured metal layer and, if appropriate, regions of the ceramic body which are exposed by the recesses in the metal layer forming the structuring, onto which no silver-containing layer is deposited in step d). In conventional masking methods, masking agent is applied to the structured metal layer, preferably as a layer, in particular over the entire surface, in an additive masking step, wherein in a subsequent subtractive masking step the solidified masking agent is removed in the areas of the structured metal layer onto which a silver-containing layer is deposited in a subsequent step. By omitting a subtractive masking step, according to this preferred embodiment, a particularly simple method for producing a metal-ceramic substrate provided with a structuring and a contact area comprising silver is advantageously provided.

According to a preferred embodiment, in step c) a mask is also applied to regions of the ceramic body which are exposed by the recesses in the metal layer forming the structuring, by applying a liquid medium comprising a masking agent to regions of the ceramic body which are exposed by the recesses in the metal layer forming the structuring, and solidifying the masking agent. Applying a mask to exposed regions of the ceramic body may be advantageous in order to protect the exposed regions of the ceramic body in step d) from deposition of a silver-containing layer.

The application of a mask to the structured metal layer and the application of a mask to areas of the ceramic body that are exposed by the recesses in the metal layer that form the structuring can be carried out simultaneously or sequentially.

For applying a mask to areas of the ceramic body which are exposed by the recesses in the metal layer forming the structuring, a liquid medium as described above with respect to applying a mask to the structured metal layer and an application as described above with respect to applying a mask to the structured metal layer can be used.

In step d), a silver-containing layer is deposited on the unmasked regions of the structured metal layer to obtain a contact area comprising silver.

The silver-containing layer is preferably a layer consisting of silver or a silver-containing alloy, particularly preferably silver. The deposition of the silver-containing layer is preferably carried out chemically (e.g., electrochemically) or physically. The chemical deposition of the silver-containing layer can be carried out, for example, galvanically or electrolessly. Preferably, the chemical deposition of the silver-containing layer is carried out electrolessly by applying a silver-containing solution, with a charge exchange between the metals, wherein metal of the metal layer partially dissolves while the silver in the solution is deposited. According to a preferred embodiment, the silver-containing solution contains a silver salt and particularly preferably silver nitrate. According to a particularly preferred embodiment, the silver-containing solution is an acidic solution of silver nitrate, and particularly preferably a nitric acid solution of silver nitrate. The concentration of silver in the nitric acid solution can, for example, be in the range of 0.5-1.5 g/l, particularly preferably in the range of 0.6-1.4 g/l and very particularly preferably in the range of 0.8-1.2 g/l. The physical deposition of the silver-containing layer can be carried out, for example, by gas phase deposition. Preferred methods for gas phase deposition are in particular electron beam deposition, laser beam deposition, arc discharge deposition or cathode sputtering.

In step e) the mask is removed.

The mask can be removed in a standard manner. For this purpose, the mask can be exposed to an alkaline solution (e.g., a 2.5% sodium hydroxide solution). After removal of the mask, the metal-ceramic substrate comprises at least one contact area comprising silver, wherein the surface of the metal layer not provided with the contact area comprising silver is freely accessible.

The method described herein makes it possible to obtain a metal-ceramic substrate which is provided with a structuring and a contact area comprising silver. By creating a contact area comprising silver, the chip can be more easily bonded to the metal-ceramic substrate using common processes such as sintering or soldering. The metal-ceramic substrate obtained in this way is characterized by a particularly high resistance to thermal shock.

### EXEMPLARY EMBODIMENTS

The present invention is described in more detail below by means of exemplary embodiments, which, however, should not be understood as limiting.

### Example 1

Example 1a—Preparation of a structured metal-ceramic substrate: For Example 1, a metal-ceramic substrate was used in which a ceramic body made of a silicon nitride ceramic with dimensions of 177.8×139×0.32 mm was bonded on both sides to a copper layer with dimensions of 170×132×0.3 mm using an AMB (Active Metal Brazing) process. This copper-ceramic substrate was first cleaned after production.

A photosensitive film was then applied to both copper layers of the copper-ceramic substrate using a hot roll laminator. The photosensitive film was exposed to 30 mJ/cm² in each of the areas to be masked in order to harden the polymer contained in the photosensitive film and to obtain an etching mask. Subsequently, the unexposed regions of the photosensitive film were removed wet-chemically using a sodium carbonate solution (concentration=10 g/l). After applying the etching mask, the copper-ceramic substrate was cleaned by rinsing. Subsequently, the unmasked regions of the copper layers of the copper-ceramic substrate were wet-chemically etched. For this purpose, the copper-ceramic substrate was sprayed in an etching system with a hydrochloric acid/copper chloride solution (copper ion content=160 g/l) containing hydrogen peroxide. Etching was carried out at a temperature of 50° C. and a spray pressure of 2.8 bar. By etching, material was removed from the unmasked regions of the copper layers of the copper-ceramic substrate. The copper-ceramic substrates were then rinsed. Then, unmasked regions of the bonding layer contained in the copper-ceramic substrate were also wet-chemically etched. For this purpose, the copper-ceramic substrate was again sprayed in an etching system with an etching solution containing ammonium fluoride, fluoroboric acid and hydrogen peroxide. The copper-ceramic substrate was then rinsed and dried. The etching mask was then removed in a stripping system using a 2.5% sodium hydroxide solution.

Example 1b—Preparation of a structured metal-ceramic substrate with a contact area comprising silver: The structured copper-ceramic substrate prepared in Example 1a was provided with a contact area comprising silver. For this purpose, a mask was first applied to a structured copper layer of the copper-ceramic substrate (including the structuring region) and regions of the ceramic body that were exposed by the recesses in the copper layer that form the structuring (exposed regions of the ceramic body). For this purpose, the structured copper-ceramic substrate was positioned in an inkjet printer (MicroCraft C4K7861T, Sense Advanced Technology GmbH) to apply a mask to the structured copper layer (including the structuring region) and the exposed regions of the ceramic body. The areas of the structured copper layer that were to remain free of silver as well as the exposed regions of the ceramic body were printed with a liquid medium containing a masking agent (DiPaMAT Etch Resist ER02). The masking agent was then cured using UV radiation (LED 390 nm, 500 mJ/cm²). Consequently, the areas of the structured copper layer that were to remain free of silver as well as the exposed regions of the ceramic body were covered with a 30 μm thick mask.

Subsequently, silver-containing contact areas were deposited on the unmasked regions of the copper layer of the copper-ceramic substrate. For this purpose, the masked copper-ceramic substrate was first pretreated with a first solution containing hydrogen peroxide and sulfuric acid, and then contacted with a nitric acid/silver nitrate solution (silver content=1.0 g/l). After deposition of the silver-containing contact areas, the copper-ceramic substrate was carefully rinsed with water to remove any residues. The mask was then removed in a stripping system using a 2.5% sodium hydroxide solution.

The resulting copper-ceramic substrate was laser cut into individual parts with the dimensions (20.5×17.0 mm) and could then be used for further investigations and the production of an electronic component.

### Comparative Example 1

Comparative Example 1a—Preparation of a structured metal-ceramic substrate: In Comparative Example 1a, a structured copper-ceramic substrate was prepared analogously to Example 1a.

Comparative Example 1b—Preparation of a structured metal-ceramic substrate with a contact area comprising silver:

The structured copper-ceramic substrate prepared in Comparative Example 1a was provided with a contact area comprising silver. For this purpose, a mask was first applied to a structured copper layer of the copper-ceramic substrate (including the structuring region) and regions of the ceramic body that were exposed by the recesses in the copper layer that form the structuring (exposed regions of the ceramic body). For this purpose, a photosensitive film was applied to the two etched surfaces of the structured copper-ceramic substrate using a hot roll laminator. The photosensitive film was exposed to 30 mJ/cm² in each of the areas to be masked in order to harden the polymer contained in the photosensitive film and to obtain the mask. The unexposed regions of the photosensitive film were then removed wet-chemically using a sodium carbonate solution (concentration=10 g/l). After applying the mask, the copper-ceramic substrate was again cleaned by rinsing. Subsequently, silver-containing contact areas were deposited on the unmasked regions of the copper layer of the copper-ceramic substrate. For this purpose, the masked copper-ceramic substrate was first pretreated with a first solution containing hydrogen peroxide and sulfuric acid, and then contacted with a nitric acid/silver nitrate solution (silver content=1.0 g/l). After deposition of the silver-containing contact areas, the copper-ceramic substrate was carefully rinsed with water to remove any residues. The mask was then removed in a stripping system using a 2.5% sodium hydroxide solution.

The resulting copper-ceramic substrate was laser cut into individual parts with the dimensions (20.5×17.0 mm) and could then be used for further investigations and the production of an electronic component.

### Evaluation:

For the copper-ceramic substrates obtained in Example 1 and Comparative Example 1, the ratio S(BC_{solid})/S(BCₜₒₜₐₗ) was determined. For this purpose, as described herein, the copper-ceramic substrates were cut perpendicular to the primary boundary surface of the respective ceramic bodies, and images of the cross-sections thus obtained were captured through a light microscope. Points A, B and C were determined in the cross-sections. Then, the ratio S(BC_{solid})/S(BCₜₒₜₐₗ) was determined for each of the copper-ceramic substrates. For this purpose, ten different cross-sections of a structuring region in the copper layer of the respective copper-ceramic substrate were examined, the ratio S(BC_{solid})/S(BCₜₒₜₐₗ) for each of these cross-sections was determined, and the average of the ratios S(BC_{solid})/S(BCₜₒₜₐₗ) for each of these cross-sections was calculated in order to arrive at the ratio S(BC_{solid})/S(BCₜₒₜₐₗ) for the respective copper-ceramic substrate. Furthermore, the standard deviation SSD was determined.

Likewise, for the copper-ceramic substrates obtained in Example 1 and Comparative Example 1, the silver content in the region adjacent to the upper half of the contour line and in the region adjacent to the lower half of the contour line was determined by energy dispersive X-ray spectroscopy (EDX) coupled with scanning electron microscopy (SEM) as described above (SEM-EDX).

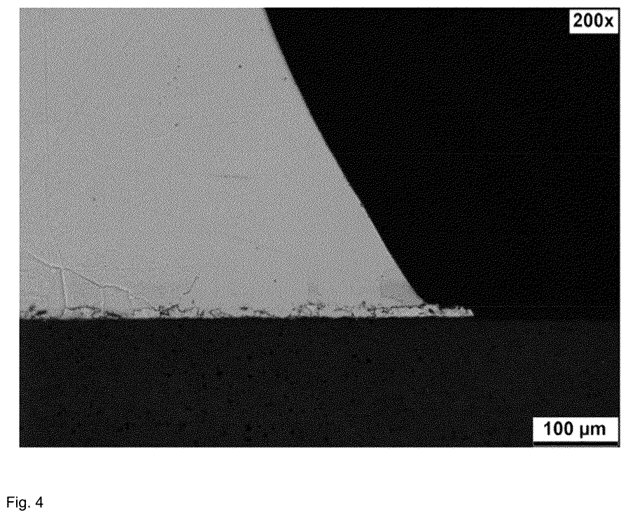

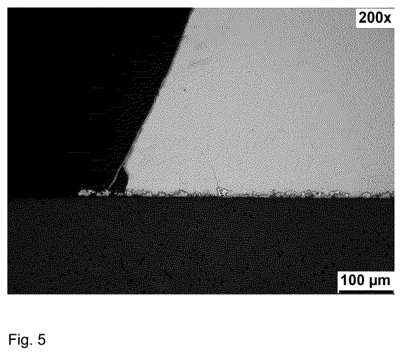

FIG. 4 shows an example of a light micrograph of the cross-section of a section of a structuring region of the copper layer of a copper-ceramic substrate according to Example 1, while FIG. 5 shows an example of a light micrograph of the cross-section of a section of a structuring region of the copper layer of a copper-ceramic substrate according to Comparative Example 1.

The results are shown in Table 1.

TABLE 1

| | | | Silver | Silver | |
|---|---|---|---|---|---|
| | | Standard | content, | content, | |
| | S (BC_{solid})/S | deviation | upper | lower | |
| | (BCₜₒₜₐₗ) | SSD | half | half | |
| Example | 98.1% | 0.6% | 85 wt. % | 1 | wt. % |
| Comparative | 58.4% | 12.7% | 76 wt. % | 81 | wt. % |
| Example | | | | | |

The copper-ceramic substrates were tested for their thermal shock resistance. For this purpose, thermal shock resistance tests were carried out.

### Thermal Shock Resistance Test:

In preparation for the thermal shock resistance test, ultrasound microscopy (PVA Tepla SAM300) was first used to check whether the copper-ceramic substrates were in perfect condition. For the test, only copper-ceramic substrates were used that showed no delamination between the ceramic body and the copper layer or other deformations that could lead to delamination of the copper layer from the ceramic body (e.g., cracks). To test the thermal shock resistance, the copper-ceramic substrates were repeatedly exposed to a cold liquid (temperature −65° C., Galden Do2TS) and a hot liquid (temperature +150° C., Galden Do2TS) in a cycling chamber (ESPEC TSB-2|5|) for a period of five minutes each. The copper-ceramic substrates were checked again every 1000 cycles for delamination and other deformations by means of ultrasound microscopy (PVA Tepla SAM300). The test was terminated after 3000 cycles. The copper-ceramic substrates were then again examined for delamination and other deformations by means of ultrasound microscopy (PVA Tepla SAM300). The condition of the respective copper-ceramic substrates after the thermal shock resistance test was compared with the condition of the copper-ceramic substrates before the thermal shock resistance test with regard to delamination and other deformations. Delaminations and other deformations (e.g., cracks) were visible as white discolorations in the ultrasound image.

The results are shown in Table 2.

TABLE 2

| | Result of the thermal shock resistance test |
|---|---|
| Example 1 | Very good: No delaminations were visible |
| Comparative | Poor: Delaminations were visible |
| Example 1 | at the corners of the copper- |
| | ceramic substrate |

The results show that the metal-ceramic substrate according to the invention is clearly superior to the metal-ceramic substrate of Comparative Example 1 with regard to thermal shock resistance.

### REFERENCE NUMERALS

1 Metal-ceramic substrate
4 Structuring region
8 Contact area
10 Ceramic body
15 Primary boundary surface of the ceramic body
20 Metal layer
22 Recess
24 Primary boundary surface of the metal layer
30 Line of best fit
40 Contour line
50 Solid material
60 Silver
200 Further metal layer

What is claimed is:

1. A metal-ceramic substrate, comprising
a) a ceramic body comprising a primary boundary surface;
b) a metal layer comprising a primary boundary surface, wherein the metal layer is connected over its surface to the ceramic body, and wherein the metal layer comprises a structuring region comprising
(i) partially solid material and
(ii) partially non-solid material;
and,
c) a contact area, comprising silver, arranged on the metal layer,
wherein in a cross-section through the metal-ceramic substrate perpendicular to the primary boundary surface of the ceramic body, the structuring region has a geometry, wherein the following requirement is met:
$$S ( {BC}_{solid} ) / S ( {BC}_{total} ) > 60 \% ,$$
S(BCₜₒₜₐₗ) stands for the total length of the line between points B and C, and S(BC_{solid}) stands for the length of the line between points B and C that intersects solid material, where points B and C are determined as follows:
(i). the line of best fit between the ceramic body and the metal layer is determined;
(ii). the contour line which separates the solid material from the non-solid material is determined;
(iii). point A, at which a perpendicular to the line of best fit intersects the contour line, is determined on the perpendicular to the line of best fit, at a distance of 150 μm from the line of best fit;
(iv). point B, at which a perpendicular to the line of best fit intersects the contour line, is determined on the perpendicular to the line of best fit, at a distance of 80 μm from the line of best fit; and,
(v). point C, at which a straight line intersects the line of best fit, is determined on the straight line passing through points A and B; and wherein the contour line extends from the primary boundary surface of the metal layer to the primary boundary surface of the ceramic body, wherein the contour line has an upper half and a lower half, wherein the upper half of the contour line extends from the primary boundary surface of the metal layer toward the primary boundary surface of the ceramic body and the lower half of the contour line extends from the primary boundary surface of the ceramic body toward the primary boundary surface of the metal layer, and wherein the solid material in the region adjacent to the upper half of the contour line has a higher silver content than in the region adjacent to the lower half of the contour line.

2. The metal-ceramic substrate according to claim 1 wherein the ceramic of the ceramic body is selected from the group consisting of aluminum nitride ceramics, silicon nitride ceramics, and aluminum oxide ceramics.

3. The metal-ceramic substrate according to claim 1 wherein the metal layer comprises copper.

4. The metal-ceramic substrate according to claim 1 wherein the solid material contains metal of the metal layer.

5. The metal-ceramic substrate according to claim 1 wherein the non-solid material contains gas-phase material.

6. The metal-ceramic substrate according claim 1 wherein a wing requirement is met:
$$S ( {BC}_{solid} ) / S ( {BC}_{total} ) > 95 \% .$$

7. The metal-ceramic substrate according claim 1 wherein the sample standard deviation SSD of the ratio S(BC_{solid})/S(BCₜₒₜₐₗ) over at least ten different cross-sections of the structuring region of the metal layer is not more than 10%.

8. The metal-ceramic substrate according to claim 1 wherein the ratio of the silver content in the solid material in the region adjacent to the lower half of the contour line to the silver content in the solid material in the region adjacent to the upper half of the contour line is less than 0.8.

9. An electronic component comprising the metal-ceramic substrate according to claim 1.

10. A method for producing a metal-ceramic substrate provided with a structuring and a contact area comprising silver, comprising the steps of:
a) providing a metal-ceramic substrate, comprising
a1) a ceramic body,
a2) a metal layer connected over its surface to the ceramic body;
b) structuring the metal layer;
c) applying a mask to the structured metal layer by applying a liquid medium comprising a masking agent to the structured metal layer in certain regions, and solidifying the masking agent;
d) depositing a silver-containing layer on the unmasked regions of the structured metal layer to obtain a contact area comprising silver; and,
e) removing the mask.
